(19) United States
(12) Patent Application Publication
(10) Pub. No.: US 2017/0063373 A1
(43) Pub. Date: Mar. 2, 2017

(54) Multiplexer

(71) Applicant: U.S.A. as represented by the Administrator of the National Aeronautics and Space Administration, Washington, DC (US)

(72) Inventors: GEORGE SUAREZ, Burtonsville, MD (US); JEFFREY J. DUMONTHIER, Ashburn, VA (US)

(21) Appl. No.: 14/843,373

(22) Filed: Sep. 2, 2015

(51) Int. Cl. H03K 17/693; H03M 1/12

(52) U.S. Cl. CPC H03K 17/693; H03M 1/1205

(57) ABSTRACT

The present invention relates to a compact, low power, radiation-hardened-by-design 8-channel analog multiplexer ASIC, a 0.25 μm complementary metal-oxide semiconductor (CMOS); a 500 krad total ionization dose and single event latchup which is greater than the linear energy transfer (LET) 120 MeV-sq. cm/mg; eight channels for 8-to-1 multiplexing; a three nanosecond break-before-make decoder; an active low enable pin; and an on-resistance of less than 500 ohms from input to output pads.

### BACKGROUND OF THE INVENTION

1. Field of the Invention

The present invention relates to a compact, low power, radiation-hardened-by-design 8-channel analog multiplexer developed for use with a 12-bit analog-to-digital converter.

2. Description of the Related Art

Conventional multiplexers are radiation hardened, but conventional +5V multiplexers fail to protect against the momentary connection of old and new signal paths during use (i.e., have no break-before-make logic), which can be detrimental to the operation of the multiplexer. Finally, access to parts for space missions including CubeSats is difficult due to budget limitations.

Thus, a multiplexer that has superior radiation tolerance, that will protect the operation of the multiplexer, and yet be compact and low power, is needed.

### SUMMARY OF THE INVENTION

The present invention relates to a compact, low power, radiation-hardened-by-design 8-channel analog multiplexer ASIC. In one embodiment, the multiplexer includes a 0.25 μm complementary metal-oxide semiconductor (CMOS); a 500 krad total ionization dose tolerance and single event latchup immunity which is greater than the linear energy transfer (LET) 120 MeV-sq. cm/mg; eight channels for 8-to-1 multiplexing; a three nanosecond break-before-make decoder; an active low enable pin; and an on-resistance of less than 500 ohms from input to output pads.

In one embodiment, the multiplexer is disposed in a 16-lead ceramic small-outline integrated circuit (SOIC) package.

In one embodiment, the multiplexer includes a 2.5-3.6 V supply and a supply ground voltage.

In one embodiment, the multiplexer is an eight-channel mixed-signal Application Specific Integrated Circuit (ASIC).

In one embodiment, the multiplexer switches between eight single-ended inputs of said eight-channels with said break-before-make decoder, where a presently-selected switch is configured to break or open before making or closing a newly-selected switch.

In one embodiment, the operating temperature is between −55° C. to 125° C., and is typically room temperature at 25° C.

In one embodiment, the multiplexer further enables operation by an external controller via the en_n and sel_{2.0} pins.

Thus has been outlined, some features consistent with the present invention in order that the detailed description thereof that follows may be better understood, and in order that the present contribution to the art may be better appreciated. There are, of course, additional features consistent with the present invention that will be described below and which will form the subject matter of the claims appended hereto.

In this respect, before explaining at least one embodiment consistent with the present invention in detail, it is to be understood that the invention is not limited in its application to the details of construction and to the arrangements of the components set forth in the following description or illustrated in the drawings. Methods and apparatuses consistent with the present invention are capable of other embodiments and of being practiced and carried out in various ways. Also, it is to be understood that the phraseology and terminology employed herein, as well as the abstract included below, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the methods and apparatuses consistent with the present invention.

### BRIEF DESCRIPTION OF THE DRAWING

FIG. 1 is a schematic drawing of an exemplary arrangement of a multiplexer according to one embodiment consistent with the present invention.

FIG. 2 is a schematic drawing of a multiplexer disposed in a package according to one embodiment consistent with the present invention.

### DESCRIPTION OF THE INVENTION

The present invention addresses the need for space-worthy, compact, multi-channel Application Specific Integrated Circuits (ASICs) to reduce the size, mass, and power of radiation-hardened instrument electronics. The ASIC features are science-driven based on applications in a realistic space environment such as housekeeping/health monitoring and instrumentation systems. The present invention is directed to a radiation-hardened multi-channel analog multiplexer ASIC that will enable miniaturized instrument electronics, and which can be fabricated in a commercial complementary metal-oxide semiconductor (CMOS) process.

In one embodiment, the present invention is a compact, low power, radiation-hardened-by-design 8-channel analog multiplexer ASIC, which selects one of several analog input signals and forwards the selected input into a single output line. The multiplexer, or data selector, is used to increase the amount of data that can be sent over a network within a certain amount of time and bandwidth. Thus, several signals can share one device or resource which, in the case of its current application, is a 12-bit analog-to-digital convertor (ADC) ASIC, instead of one device per input signal. The sel wires control connection of the desired input to the output.

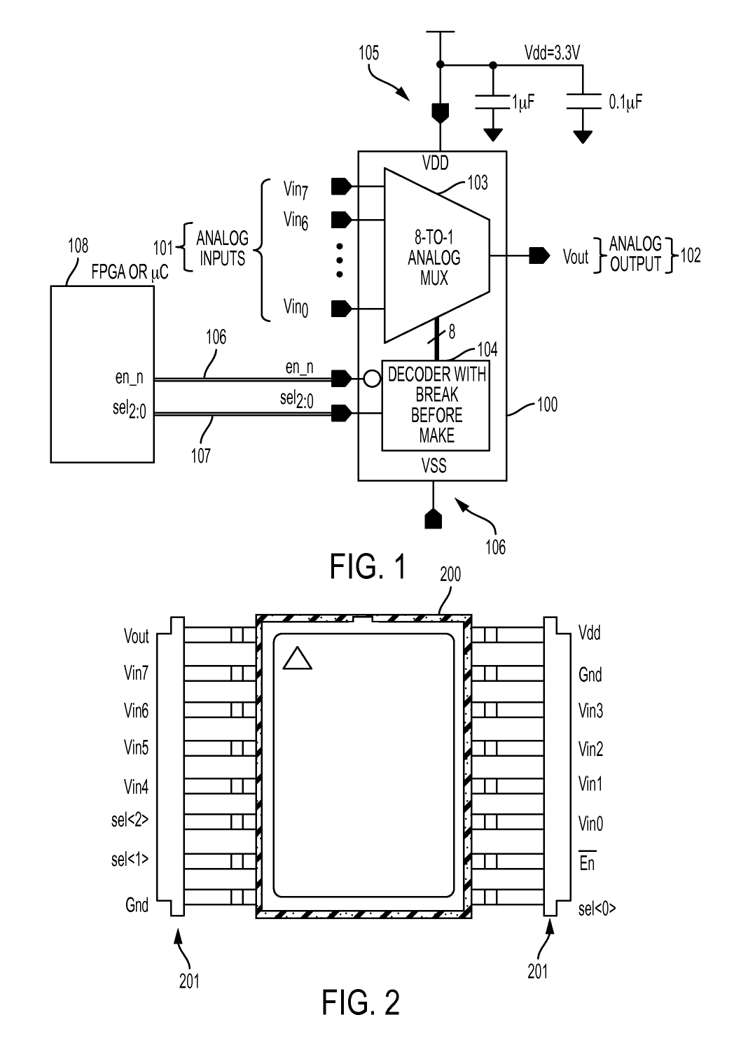

The present invention, as shown in FIG. 1, includes features such as: radiation-hardened by design in a commercial 0.25 μm CMOS process; a 500 krad total ionization dose (TID) (which degrades parts over time) and single event latchup immunity (SEL) (for a catastrophic event, such as a current surge), which is greater than the linear energy transfer (LET) 120 MeV-sq. cm/mg; a single 3.3 V (range 2.5-3.6 V) supply; 8 channels for an 8-to-1 multiplexing; a 3 ns break-before-make decoder; an active low enable pin; an on-resistance <500 ohms from input to output pads; and an exemplary, compact, 16-lead ceramic small outline integrated circuit (SOIC) package (chosen for its flight worthiness, availability and low cost) (see FIG. 2).

In contrast, available radiation hardened +5V devices have no break-before-make logic. Further, access to parts for low-class missions including small satellites (i.e., CubeSats) is difficult due to budget limitations.

More specifically, the ADC ASIC, of which the present invention was developed as part, utilizes the analog multiplexer to switch between 8 single ended inputs with the break-before-make decoder. The ASIC operates as follows.

The multiplexer of the present invention is connected to a supply voltage V_{dd} (3.0-3.6 V, typically 3.3 V), and a supply ground voltage Vss (−0.1-0.1, typically 0.0V). Its operating temperature is between −55° C. to 125° C. (typically room temperature at 25° C.).

Different signals are applied to the 8 input pins (Vᵢₙ₀-Vᵢₙ₇) while the en_n and sel_{2.0} are set to enable and select the input that appears at the analog output Vₒᵤₜ pin through a CMOS switch. The analog mux on-resistance is 500 Ohms. The Decoder contains a break-before-make feature where the presently-selected switch is configured to break (open) before making (closing) the newly-selected switch. This prevents the momentary connection of the old and new signal paths.

The multiplexer of the present invention is typically operated using an external controller such as a FPGA or microcontroller (μC) to set the en_n and sel_{2.0} pins (see FIG. 1). It is recommended that sensitive analog and output signals are shielded with the ASIC ground and use bypass capacitors (i.e., ceramic 1 uF in parallel with a 0.1 uF) from Vdd to Vₛₛ.

In one embodiment, the package for the multiplexer of the present invention is shown in FIG. 2. The die can be packaged in different configurations and packages such as SOIC and flatpacks (SOIC). In one embodiment, the multiplexer is packaged in a standard 16-lead ceramic SOIC package (see FIG. 2) following MIL-STD procedures using silver glass (J7000) for die attach and 1.25 mil (wedge) aluminum wires. The SOIC 16-package can be inserted in a standard test socket (i.e., ENPLAS FP-24(28)-1.27-07) for burn-in/testing.

In one embodiment, the I/O pad has the following signals with corresponding I/O pad description.

The V_{dd} pad has the V_{dd} signal, which is a 3.3V supply; the Vₛₛ pad is the ground signal; Vₒᵤₜ is the analog multiplexer output, which has an analog I/O pad with 100 ohms series resistor and ESD diodes; V_{in[7.0]} is the analog multiplexer inputs, which correspond to the analogy I/O pad with 100 ohms series resistor and ESD diodes; en_n is the decoder enable, which has an I/O pad which is the digital input (Schmitt trigger) pad with 200 ohms series resistor, ESD diodes and 100 kOhms pull-down; and sel_{[2:0]} is an analog multiplexer select signals, which I/O pad is the digital input (Schmitt trigger) pad with 200 ohms series resistor, ESD diodes and 100 kOhms pull down.

Accordingly, the multiplexer of the present invention as described above, is superior to state-of-the-art commercial multiplexers, and has great commercial potential for use in military and space electronic components.

It should be emphasized that the above-described embodiments of the invention are merely possible examples of implementations set forth for a clear understanding of the principles of the invention. Variations and modifications may be made to the above-described embodiments of the invention without departing from the spirit and principles of the invention. All such modifications and variations are intended to be included herein within the scope of the invention and protected by the following claims.

What is claimed is:

1. An analog multiplexor developed for analog-to-digital converter applications comprising:
a 0.25 μm complementary metal-oxide semiconductor (CMOS);
a 500 krad total ionization dose and single event latchup immunity which is greater than the linear energy transfer (LET) 120 MeV-sq. cm/mg;
eight channels for 8-to-1 multiplexing;
a three nanosecond break-before-make decoder;
an active low enable pin; and
an on-resistance of less than 500 ohms from input to output pads.

2. The multiplexer of claim 1, wherein the multiplexer is radiation-hardened.

3. The multiplexer of claim 1, further comprising a 16-lead ceramic small-outline integrated circuit (SOIC) package in which the multiplexer is disposed.

4. The multiplexer of claim 1, further comprising a 2.5-3.6 V supply.

5. The multiplexer of claim 1, wherein the multiplexer is an eight-channel mixed-signal Application Specific Integrated Circuit (ASIC).

6. The multiplexer of claim 5, wherein the multiplexer switches between eight single-ended inputs of said eight-channels with said break-before-make decoder, where a presently-selected switch is configured to break or open before making or closing a newly-selected switch.

7. The multiplexer of claim 4, further comprising a supply ground voltage.

8. The multiplexer of claim 1, wherein an operating temperature is between −55° C. to 125° C., and is typically room temperature at 25° C.

9. The multiplexer of claim 5, further comprising:
an external controller which operates the multiplexer by setting the en_n and sel_{2.0} pins; and
a ground capacitor and a bypass capacitor.
